(19) United States
(12) Patent Application Publication
(10) Pub. No.: US 2005/0064307 A1
(43) Pub. Date: Mar. 24, 2005

(54) Dye-containing negative-type curable composition, color filter, and method of producing the same

(75) Inventor: Toru Fujimori, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/942,831

(22) Filed: Sep. 17, 2004

(30) Foreign Application Priority Data
Sep. 19, 2003 (JP) 2003-327573
Sep. 19, 2003 (JP) 2003-327574

(51) Int. Cl. G03F 9/00

(52) U.S. Cl. 430/7

(57) ABSTRACT

A dye-containing negative-type curable composition including at least (A) an alkali-soluble binder, (B) an organic solvent-soluble dye, (C) a photopolymerization initiator, (D) a photopolymerizable compound, and (E) an organic solvent, wherein the organic solvent (E) contains two or more kinds of organic solvents, or the organic solvent (E) contains a high-boiling solvent having a boiling point of 160° C. or more.

### CROSS-REFERENCE TO RELATED APPLICATION

This application claims priority under 35 USC 119 from Japanese Patent Application Nos. 2003-327573 and 2003-327574, the disclosures of which are incorporated by reference herein.

### BACKGROUND OF THE INVENTION

1. Field of the Invention

The present invention relates to a dye-containing negative-type curable composition suitable for formation of a color image constituting a color filter used in liquid crystal display devices (LCD) and solid-state image pickup devices (CCD, CMOS, etc.), as well as a color filter using the dye-containing negative-type curable composition and a method of producing the same.

2. Description of the Related Art

As methods of producing a color filter used in liquid crystal display devices and solid-state image pickup devices, a pigment-dispersing method, a dyeing method, a printing method and an electrodeposition method are known.

Among these methods, the pigment-dispersing method is a method of producing color filters by a photolithographic method using colored radiosensitive compositions comprising pigments dispersed in various photosensitive compositions, and because pigments are used, this method is advantageous in that the resulting color filters are stable to light, heat, etc. Further because patterning is carried out by the photolithographic method, the method is utilized widely as a method suitable for production of color filters for highly detailed, large-screen color displays with high positional accuracy.

When a color filter is produced by the pigment-dispersing method, a radiosensitive composition is applied onto a glass substrate by a spin coater, a roller coater, or the like, and then dried to form a coating. Then, the formed coating is subjected to pattern light exposure and development to form colored pixels. This operation can be repeatedly conducted for each color to obtain a color filter.

In the pigment-dispersing method, a negative-type photosensitive composition using a photopolymerizable monomer and a photopolymerization initiator together in an alkali-soluble resin has been proposed (see, for example, Japanese Patent Application Laid-Open (JP-A) Nos. 2-181704, 2-199403, 5-273411, 7-140654).

In recent years, achievement of even higher detail is demanded in color filters requiring fine patterns such as color filters for solid-state image pickup devices. In the conventional pigment dispersion system, however, there is a problem in that improvement of resolution is difficult, and color irregularities are caused by coarse pigment particles. Accordingly, the conventional pigment dispersion system is not suitable for uses such as solid-state image pickup devices, which require fine patterns.

In response to these problems, techniques of using dyes in place of the pigments have been proposed (see, for example, JP-A No. 6-75375). However, there is a problem in that such dye-containing curable compositions are generally inferior to pigment-containing compositions in performance such as light fastness, heat resistance, solubility and coating uniformity.

Particularly in preparation of color filters for solid-state image pickup devices, a coating thickness of 1.5 μm or less is required, and therefore a large amount of dye must be added to the curable composition. Accordingly, there arises the problem of significantly inferior pattern formability, such as insufficient adhesion to a substrate, failure to achieve sufficient curing, and the occurrence of missing dye in a light-exposed region (reduction in the degree of residual color in a light-exposed region).

Further, color density, saturation, and the like should be uniform for forming an image excellent in reproducibility. Particularly in the preparation of color filters for solid-state image pickup devices, since individual patterns are very fine, when coating thickness, etc. are not uniform, color density and the like are easily affected. Therefore, there is particular demand for the uniformity of a coating (uniformity of coating thickness) for use in producing color filters for solid-state image pickup devices.

### SUMMARY OF THE INVENTION

The present invention has been made in view of the above circumstances and provides a dye-containing negative-type curable composition suitable for using a dye, and specifically, the invention first provides a dye-containing negative-type curable composition in which a degree of residual color is prevented from being reduced in a light-exposed region, and secondly provides a dye-containing negative-type curable composition that is excellent in coating uniformity. Furthermore, the invention provides a color filter-producing method capable of producing an excellent color filter and simultaneously exhibiting high cost performance.

A first aspect of the invention is to provide a dye-containing negative-type curable composition comprising at least (A) an alkali-soluble binder, (B) an organic solvent-soluble dye, (C) a photopolymerization initiator, (D) a photopolymerizable compound, and (E) an organic solvent, wherein the organic solvent (E) contains two or more kinds of organic solvents.

A second aspect of the invention is to provide a color filter comprising a dye-containing negative-type curable composition used therein, the composition comprising at least (A) an alkali-soluble binder, (B) an organic solvent-soluble dye, (C) a photopolymerization initiator, (D) a photopolymerizable compound, and (E) an organic solvent, wherein the organic solvent (E) contains two or more kinds of organic solvents.

A third aspect of the invention is to provide a method of producing a color filter, which comprises applying a dye-containing negative-type curable composition onto a support, exposing the composition to light through a mask, and developing the composition to form a pattern,
the composition comprising at least (A) an alkali-soluble binder, (B) an organic solvent-soluble dye, (C) a photopolymerization initiator, (D) a photopolymerizable compound, and (E) an organic solvent, wherein the organic solvent (E) contains two or more kinds of organic solvents.

A fourth aspect of the invention is to provide a dye-containing negative-type curable composition comprising at least (A) an alkali-soluble binder, (B) an organic solvent-soluble dye, (C) a photopolymerization initiator, (D) a photopolymerizable compound, and (E) an organic solvent, wherein the organic solvent (E) contains a high-boiling solvent having a boiling point of 160° C. or more.

A fifth aspect of the invention is to provide a color filter comprising a dye-containing negative-type curable composition used therein, the composition comprising at least (A) an alkali-soluble binder, (B) an organic solvent-soluble dye, (C) a photopolymerization initiator, (D) a photopolymerizable compound, and (E) an organic solvent, wherein the organic solvent (E) contains a high-boiling solvent having a boiling point of 160° C. or more.

A sixth aspect of the invention is to provide a method of producing a color filter, which comprises applying a dye-containing negative-type curable composition onto a support, exposing the composition to light through a mask, and developing the composition to form a pattern,
the composition comprising at least (A) an alkali-soluble binder, (B) an organic solvent-soluble dye, (C) a photopolymerization initiator, (D) a photopolymerizable compound, and (E) an organic solvent, wherein the organic solvent (E) contains a high-boiling solvent having a boiling point of 160° C. or more.

### DETAILED DESCRIPTION OF THE INVENTION

A first dye-containing negative-type curable composition of the present invention is a dye-containing negative-type curable composition comprising at least (A) an alkali-soluble binder, (B) an organic solvent-soluble dye, (C) a photopolymerization initiator, (D) a photopolymerizable compound, and (E) an organic solvent, wherein the organic solvent (E) contains two or more kinds of organic solvents.

The first dye-containing negative-type curable composition of the invention can sufficiently suppress the occurrence of missing color (reduction in the degree of residual color in a light-exposed region), that is, a change (reduction) in coating thickness and transmittance in a light-exposed region from before to after light exposure and development, by using two or more kinds of organic solvents as the organic solvent (E).

A second dye-containing negative-type curable composition of the invention comprises at least (A) an alkali-soluble binder, (B) an organic solvent-soluble dye, (C) a photopolymerization initiator, (D) a photopolymerizable compound, and (E) an organic solvent, wherein the organic solvent (E) contains a high-boiling solvent having a boiling point of 160° C. or more.

According to the second dye-containing negative-type curable composition of the invention, coating uniformity upon formation of a coating formed by applying and drying the second dye-containing negative-type curable composition of the invention can be improved by including a high-boiling solvent having a boiling point of 160° C. or more (hereinafter, also referred to as “the high-boiling solvent of the invention”) in the organic solvent (E). As used herein, coating uniformity means that coating thickness or the like is uniform. When the composition is excellent in coating uniformity, a color filter formed by using the composition can, for example, form uniform images excellent in pattern uniformity and free of unevenness.

Hereinafter, the first and second dye-containing negative-type curable compositions of the invention (hereafter, also referred to collectively as “the dye-containing negative-type curable composition of the invention”), a color filter constituted by using the dye-containing negative-type curable composition, and a method of producing the same are described in more detail.

Dye-Containing Negative-Type Curable Composition

Each of the first and second dye-containing negative-type curable compositions of the invention comprises at least (A) an alkali-soluble binder, (B) an organic solvent-soluble dye, (C) a photopolymerization initiator, (D) a photopolymerizable compound (radical polymerizable monomer), (E) an organic solvent, and optionally, other components such as a crosslinking agent. Each component will be hereinafter described and the description will be common to the first and the second dye-containing negative-type curable compositions of the invention unless otherwise specified.

(A) Alkali-Soluble Binder

Now, the alkali-soluble binder is described. The alkali-soluble binder of the invention is not particularly limited insofar as it is alkali-soluble, but is selected preferably from the viewpoint of heat resistance, developability, availability etc.

The alkali-soluble binder is preferably a linear organic high-molecular polymer which is soluble in an organic solvent and developable in an aqueous solution of a weak alkali. Examples of the linear organic high-molecular polymers include a polymer having a carboxylic acid in its side chain, such as a methacrylic acid copolymer, an acrylic acid copolymer, an itaconic acid copolymer, a crotonic acid copolymer, a maleic acid copolymer and a partially esterified maleic acid copolymer described in for example JP-A No. 59-44615, Japanese Patent Application Publication (JP-B) Nos. 54-34327, 58-12577, 54-25957, JP-A Nos. 59-53836 and 59-71048. An acidic cellulose derivative having a carboxylic acid in its side chain is also useful.

In addition to these compounds, a compound obtained by adding an acid anhydride to a hydroxyl-containing polymer, polyhydroxystyrene resin, polysiloxane resin, poly(2-hydroxyethyl(meth)acrylate), polyvinyl pyrrolidone, polyethylene oxide, polyvinyl alcohol etc. are also useful as the alkali-soluble binder.

The alkali-soluble binder may be the one wherein hydrophilic monomers were copolymerized. Examples of the hydrophilic monomers include alkoxyalkyl (meth)acrylate, hydroxyalkyl (meth)acrylate, glycerol (meth)acrylate, (meth)acrylamide, N-methylol acrylamide, secondary or tertiary alkyl acrylamide, dialkyl aminoalkyl (meth)acrylate, morpholine (meth)acrylate, N-vinyl pyrrolidone, N-vinyl caprolactam, vinyl imidazole, vinyl triazole, methyl (meth)acrylate, ethyl (meth)acrylate, branched or straight-chain propyl (meth)acrylate, branched or straight-chain butyl (meth)acrylate, phenoxyhydroxypropyl (meth)acrylate etc.

As the hydrophilic monomers, monomers having a tetrahydrofurfuryl group, phosphoric acid, a phosphate, a quaternary ammonium salt, an ethylene oxy chain, a propylene oxy chain, sulfonic acid and a salt thereof, a morpholinoethyl group, etc. are also useful.

To improve the efficiency of crosslinking, the alkali-soluble binder may have a polymerizable group in its side chain, and for example polymers having an allyl group, (meth)acryl group, allyloxyalkyl group etc. in their side chain are also useful. Examples of the polymers having one or more of such polymerizable groups include commercial products such as KS Resist-106 (trade name, manufactured by Osaka Organic Chemical Industry Ltd.), Cyclomer P series (manufactured by Daicel Chemical Industries, Ltd.) etc. To increase the strength of a cured coating, alcohol-soluble nylon, a 2,2-bis-(4-hydroxyphenyl)-propane/epichlorohydrin polyether, etc. are also useful.

Among these alkali-soluble binders, polyhydroxystyrene resin, polysiloxane resin, acrylic resin, acrylamide resin, and acryl/acrylamide copolymer resin are preferable from the viewpoint of heat resistance, and acrylic resin, acrylamide resin and acryl/acrylamide copolymer resin are preferable from the viewpoint of regulation of developability.

The acrylic resin includes copolymers consisting of monomers selected from benzyl (meth)acrylate, (meth)acrylic acid, hydroxyethyl (meth)acrylate and (meth)acrylamide, and for example, commercial products such as KS Resist-106 (trade name, manufactured by Osaka Organic Chemical Industry Ltd.), Cyclomer P series (trade name, manufactured by Daicel Chemical Industries, Ltd.) etc. are preferable.

The alkali-soluble binder is preferably a polymer having a weight average molecular weight (polystyrene-equivalent molecular weight determined by GPC) of 1,000 to 200,000, more preferably 2,000 to 100,000, and still more preferably 5,000 to 50,000. When the weight average molecular weight is in the range of 1,000 to 200,000, the dye-containing negative-type curable composition exhibits excellent solubility, filterability and coating properties to form a good coating film.

The content of the alkali-soluble binder in the dye-containing negative-type curable composition is preferably 10 to 90% by mass, more preferably 20 to 80% by mass, and still more preferably 30 to 70% by mass, based on the total solids content (mass) of the composition. When the content is in the range of 10 to 90% by mass, the dye-containing negative-type curable composition can show good coating properties to form a good coating film and simultaneously give a good pattern-forming ability.

(B) Organic Solvent-Soluble Dye

The organic solvent-soluble dye can be used without particular limitation insofar as it is a dye soluble in an organic solvent, and examples include known dyes for color filters. The known dyes include dyes described in, for example, JP-A Nos. 64-90403, 64-91102, 1-94301, 6-11614, Japanese Patent No. 2592207, U.S. Pat. Nos. 4,808,501, 5,667,920 and 5,059,500, JP-A Nos. 5-333207, 6-35183, 6-51115, 6-194828 etc.

From the viewpoint of chemical structure, dyes based on triphenylmethane, anthraquinone, benzylidene, oxonol, cyanine, phenothiazine, pyrrolopyrazole azomethine, xanthene, phthalocyanine, benzopyran and indigo can be used as the organic solvent-soluble dyes. Dyes based on pyrazole azo, anilinoazo, pyrazolotriazole azo, pyridone azo, anthraquinone and anthrapyridone are particularly preferable.

In a resist system where water or alkali development is carried out, an acidic dye and/or its derivative can be preferably used in some cases from the viewpoint of complete removal of the binder and/or the dye by the development. In addition, direct dyes, basic dyes, mordant dyes, acidic mordant dyes, azoic dyes, disperse dyes, oil-soluble dyes, food dyes and/or derivatives thereof can also be usefully used.

Acidic Dye

Now, the acidic dye is described. The acidic dye is not particularly limited insofar as it is a dye having sulfonic acid, carboxylic acid or an acidic group such as a phenolic hydroxyl group, and the acidic dye is selected in consideration of every necessary performance such as solubility in an organic solvent or a developing solution, an ability to form a salt with a basic compound, absorbance, interaction with other components in the curable composition, light fastness and heat resistance.

Hereinafter, examples of the acidic dye are described. However, the invention is not limited thereto. The acidic dye includes, for example:
acid alizarin violet N;
acid black 1, 2, 24, 48;
acid blue 1, 7, 9, 15, 18, 23, 25, 27, 29, 40, 42, 45, 51, 62, 70, 74, 80, 83, 86, 87, 90, 92, 96, 103, 112, 113, 120, 129, 138, 147, 150, 158, 171, 182, 192, 210, 242, 243, 256, 259, 267, 278, 280, 285, 290, 296, 315, 324: 1, 335, 340;
acid chrome violet K;
acid Fuchsin;
acid green 1, 3, 5, 9, 16, 25, 27, 50, 58, 63, 65, 80, 104, 105, 106, 109;
acid orange 6, 7, 8, 10, 12, 26, 50, 51, 52, 56, 62, 63, 64, 74, 75, 94, 95, 107, 108, 169, 173;
acid red 1, 4, 8, 14, 17, 18, 26, 27, 29, 31, 34, 35, 37, 42, 44, 50, 51, 52, 57, 66, 73, 80, 87, 88, 91, 92, 94, 97, 103, 111, 114, 129, 133, 134, 138, 143, 145, 150, 151, 158, 176, 182, 183, 198, 206, 211, 215, 216, 217, 227, 228, 249, 252, 257, 258, 260, 261, 266, 268, 270, 274, 277, 280, 281, 195, 308, 312, 315, 316, 339, 341, 345, 346, 349, 382, 383, 394, 401, 412, 417, 418, 422, 426;
acid violet 6 B, 7, 9, 17, 19;
acid yellow 1, 3, 7, 9, 11, 17, 23, 25, 29, 34, 36, 38, 40, 42, 54, 65, 72, 73, 76, 79, 98, 99, 111, 112, 113, 114, 116, 119, 123, 128, 134, 135, 138, 139, 140, 144, 150, 155, 157, 160, 161, 163, 168, 169, 172, 177, 178, 179, 184, 190, 193, 196, 197, 199, 202, 203, 204, 205, 207, 212, 214, 220, 221, 228, 230, 232, 235, 238, 240, 242, 243, 251;
Direct Yellow 2, 33, 34, 35, 38, 39, 43, 47, 50, 54, 58, 68, 69, 70, 71, 86, 93, 94, 95, 98, 102, 108, 109, 129, 136, 138, 141;
Direct Orange 34, 39, 41, 46, 50, 52, 56, 57, 61, 64, 65, 68, 70, 96, 97, 106, 107;
   Direct Red 79, 82, 83, 84, 91, 92, 96, 97, 98, 99, 105, 106, 107, 172, 173, 176, 177, 179, 181, 182, 184, 204, 207, 211, 213, 218, 220, 221, 222, 232, 233, 234, 241, 243, 246, 250;
Direct Violet 47, 52, 54, 59, 60, 65, 66, 79, 80, 81, 82, 84, 89, 90, 93, 95, 96, 103, 104;
Direct Blue 57, 77, 80, 81, 84, 85, 86, 90, 93, 94, 95, 97, 98, 99, 100, 101, 106, 107, 108, 109, 113, 114, 115, 117, 119, 137, 149, 150, 153, 155, 156, 158, 159, 160, 161, 162, 163, 164, 166, 167, 170, 171, 172, 173, 188, 189, 190, 192, 193, 194, 196, 198, 199, 200, 207, 209, 210, 212, 213, 214, 222, 228, 229, 237, 238, 242, 243, 244, 245, 247, 248, 250, 251, 252, 256, 257, 259, 260, 268, 274, 275, 293;
Direct Green 25, 27, 31, 32, 34, 37, 63, 65, 66, 67, 68, 69, 72, 77, 79, 82;
Mordant Yellow 5, 8, 10, 16, 20, 26, 30, 31, 33, 42, 43, 45, 56, 50, 61, 62, 65;
Mordant Orange 3, 4, 5, 8, 12, 13, 14, 20, 21, 23, 24, 28, 29, 32, 34, 35, 36, 37, 42, 43, 47, 48;
Mordant Red 1, 2, 3, 4, 9, 11, 12, 14, 17, 18, 19, 22, 23, 24, 25, 26, 30, 32, 33, 36, 37, 38, 39, 41, 43, 45, 46, 48, 53, 56, 63, 71, 74, 85, 86, 88, 90, 94, 95;
Mordant Violet 2, 4, 5, 7, 14, 22, 24, 30, 31, 32, 37, 40, 41, 44, 45, 47, 48, 53, 58;
Mordant Blue 2, 3, 7, 8, 9, 12, 13, 15, 16, 19, 20, 21, 22, 23, 24, 26, 30, 31, 32, 39, 40, 41, 43, 44, 48, 49, 53, 61, 74, 77, 83, 84;
Mordant Green 1, 3, 4, 5, 10, 15, 19, 26, 29, 33, 34, 35, 41, 43, 53;
Food Yellow 3;
   and derivatives of these dyes.

Preferably used among the acidic dyes described above are dyes such as acid black 24; acid blue 23, 25, 29, 62, 80, 86, 87, 92, 138, 158, 182, 243, 324: 1; acid orange 8, 51, 56, 74, 63, 74; acid red 1, 4, 8, 34, 37, 42, 52, 57, 80, 97, 114, 143, 145, 151, 183, 217; acid violet 7; acid yellow 17, 25, 29, 34, 42, 72, 76, 99, 111, 112, 114, 116, 134, 155, 169, 172, 184, 220, 228, 230, 232, 243; Acid Green 25; and derivatives of these dyes.

Azo, xanthene or phthalocyanine acidic dyes other than those described above are also preferable, and acidic dyes such as C. I. Solvent Blue 44, 38; C. I. Solvent Orange 45; Rhodamine B; Rhodamine 110; 2,7-Naphthalenedisulfonic acid; 3-[(5-chloro-2-phenoxyphenyl)hydrazono]-3,4-dihydro-4-oxo-5-[(phenylsulfonyl)amino]- or derivatives of these dyes can also be preferably used.

As the derivatives of the acidic dyes, an inorganic salt of the acidic dye having an acidic group such as sulfonic acid and carboxylic acid, a salt of the acidic dye with a nitrogen-containing compound, and a sulfonamide derivative of the acidic dye can be used. The derivatives of the acidic dyes are not particularly limited insofar as they can be dissolved in a solution of the curable composition, and the derivatives of the acidic dyes are selected in consideration of every necessary performance such as solubility in an organic solvent or a developing solution, absorbance, interaction with other components in the curable composition, light fastness and heat resistance.

Now, the salt of the acidic dye with a nitrogen-containing compound is described. The method of forming the salt of the acidic dye with a nitrogen-containing compound may be effective in improving the solubility of the acidic dye (conferment of solubility on the organic solvent) and in improving heat resistance and light fastness.

The nitrogen-containing compound is selected in consideration of the solubility of the salt or amide compound in an organic solvent or a developing solution, an ability to form the salt, the absorbance and color value thereof as the dye, interaction with other components in the curable composition, and the heat resistance and light fastness thereof asa colorant. In selection from the viewpoint of only absorbance and color value, the nitrogen-containing compound preferably has a smaller molecular weight, particularly a molecular weight of preferably 300 or less, more preferably 280 or less, and still more preferably 250 or less.

Now, the nitrogen-containing compound/acidic dye molar ratio (hereinafter referred to as “n”) in the salt of the acidic dye with the nitrogen-containing compound is described. The molar ratio n is a value determining the molar ratio of the acidic dye molecule to the amine compound as counter ion, and can be arbitrarily selected depending on the conditions for forming the acidic dye/amine compound salt. In the number of functional groups of the acid in the acidic dye, a numerical value satisfying the relationship 0<n≦5 is practically used in many cases, and is selected in consideration of every necessary performance such as solubility in an organic solvent or a developing solution, an ability to form the salt, absorbance, interaction with other components in the curable composition, light fastness and heat resistance. When selected from the viewpoint of only absorbance, n is a numerical value of preferably 0<n≦4.5, more preferably 0<n≦4, and still more preferably 0<n≦3.5.

The above-mentioned acidic dye is made acidic by introducing an acidic group into its structure. Accordingly, the dye can be converted into a non-acidic dye by changing the substituent group.

The reason for this is because, although there are cases where the acidic dye can be preferably used, there are times when the acidic dye undergoes excessive development, and thus, there are also cases where it is preferable to use the non-acidic dye.

Now, the content of the organic solvent-soluble dye is described. The content of the organic solvent-soluble dye in the solids content of the dye-containing negative-type curable composition of the invention is varied depending on the dye, but is preferably 0.5 to 80% by mass, more preferably 0.5 to 60% by mass, and still more preferably 0.5 to 50% by mass, from the viewpoint of solubility, coating properties and transmittance.

(C) Photopolymerization Initiator

Now, the photopolymerization initiator is described. The photopolymerization initiator is contained together with a photopolymerizable compound described later. The photopolymerization initiator is not particularly limited insofar as it can polymerize the photopolymerizable compound described later, but the initiator is selected preferably from the viewpoint of characteristics, initiation efficiency, absorption wavelength, availability and cost.

Examples of the above-mentioned photo-polymerization initiator include at least one active halogen compound selected from a halomethyl oxadiazole compound and a halomethyl-s-triazine compound; a 3-aryl-substituted coumarin compound; a lophine dimer; a benzophenone compound; an acetophenone compound and derivatives thereof; a cyclopentadiene-benzene-iron complex and a salt thereof; and an oxime compound.

Examples of the active halogen compound that is a halomethyl oxadiazole compound include a 2-halomethyl-5-vinyl-1,3,4-oxadiazole compound and the like, described in JP-B No. 57-6096, 2-trichloromethyl-5-styryl-1,3,4-oxadiazole, 2-trichloromethyl-5-(p-cyanostyryl)-1,3,4-oxadiazole, 2-trichloromethyl-5-(p-methoxystyryl)-1,3,4-oxadiazole.

Examples of the active halogen compound that is a halomethyl-s-triazine compound include a vinyl-halomethyl-s-triazine compound disclosed in JP-B No. 59-1281, a 2-(naphtho-1-yl)-4,6-bis-halomethyl-s-triazine compound and a 4-(p-aminophenyl)-2,6-di-hallomethyl-s-triazine compound, described in JP-A No. 53-133428.

Specific examples of the photopolymerization initiator include 2,4-bis(trichloromethyl)-6-p-methoxystyryl-s-triazine, 2,6-bis(trichloromethyl)-4-(3,4-methyleneoxy phenyl)-1,3,5-triazine, 2,6-bis(trichloromethyl)-4-(4-methoxyphenyl)-1,3,5-triazine, 2,4-bis(trichloromethyl)-6-(1-p-dimethylaminophenyl-1,3-butadienyl)-s-triazine, 2-trichloromethyl-4-amino-6-p-methoxystyryl-s-triazine, 2-(naphtho-1-yl)-4,6-bis-trichloromethyl-s-triazine, 2-(4-methoxy-naphtho-1-yl)-4,6-bis-trichloromethyl-s-triazine, 2-(4-methoxy-naphtho-1-yl)-4,6-bis-trichloromethyl-s-triazine, 2-(4-ethoxy-naphtho-1-yl)-4,6-bis-trichloromethyl-s-triazine, 2-(4-butoxy-naphtho-1-yl)-4,6-bis-trichloromethyl-s-triazine, 2-[4-(2-methoxyethyl)-naphtho-1-yl]-4,6-bis-trichloromethyl-s-triazine, 2-[4-(2-ethoxyethyl)-naphtho-1-yl]-4,6-bis-trichloromethyl-s-triazine, 2-[4-(2-butoxyethyl)-naphtho-1-yl]-4,6-bis-trichloromethyl-s-triazine, 2-(2-methoxy-naphtho-1-yl)-4,6-bis-trichloromethyl-s-triazine, 2-(6-methoxy-5-methyl-naphtho-2-yl)-4,6-bis-trichloromethyl-s-triazine, 2-(6-methoxy-naphtho-2-yl)-4,6-bis-trichloromethyl-s-triazine, 2-(5-methoxy-naphtho-1-yl)-4,6-bis-trichloromethyl-s-triazine, 2-(4,7-dimethoxy-naphtho-1-yl)-4,6-bis-trichloromethyl-s-triazine, 2-(6-ethoxy-naphtho-2-yl)-4,6-bis-trichloromethyl-s-triazine, 2-(4,5-dimethoxy-naphtho-1-yl)-4,6-bis-trichloromethyl-s-triazine, 4-[p-N,N-di(ethoxycarbonylmethyl) aminophenyl]-2,6-di(trichloromethyl)-s-triazine, 4-[o-methyl-p-N,N-di(ethoxycarbonylmethyl) aminophenyl]-2,6-di(trichloromethyl)-s-triazine, 4-[p-N,N-di(chloroethyl) aminophenyl]-2,6-di(trichloromethyl)-s-triazine, 4-[o-methyl-p-N,N-di(chloroethyl) aminophenyl]-2,6-di(trichloromethyl)-s-triazine, 4-(p-N-chloroethyl aminophenyl)-2,6-di(trichloromethyl)-s-triazine, 4-(p-N-ethoxycarbonylmethyl aminophenyl)-2,6-di(trichloromethyl)-s-triazine, 4-[p-N,N-di(phenyl) aminophenyl]-2,6-di(trichloromethyl)-s-triazine, 4-(p-N-chloroethylcarbonyl aminophenyl)-2,6-di(trichloromethyl)-s-triazine, 4-[p-N-(p-methoxyphenyl) carbonylaminophenyl]-2,6-di(trichloromethyl)-s-triazine, 4-[m-N,N-di(ethoxycarbonylmethyl) aminophenyl]-2,6-di(trichloromethyl)-s-triazine, 4-[m-bromo-p-N,N-di(ethoxycarbonylmethyl) aminophenyl]-2,6-di(trichloromethyl)-s-triazine, 4-[m-chloro-p-N,N-di(ethoxycarbonyl methyl) aminophenyl]-2,6-di(trichloromethyl)-s-triazine, 4-[m-fluoro-p-N,N-di(ethoxycarbonylmethyl) aminophenyl]-2,6-di(trichloromethyl)-s-triazine, 4-[o-bromo-p-N,N-di(ethoxycarbonylmethyl) aminophenyl]-2,6-di(trichloromethyl)-s-triazine, 4-[o-chloro-p-N,N-di(ethoxycarbonylmethyl) aminophenyl]-2,6-di(trichloromethyl)-s-triazine, 4-[o-fluoro-p-N,N-di(ethoxycarbonylmethyl) aminophenyl]-2,6-di(trichloromethyl)-s-triazine, 4-[o-bromo-p-N,N-di(chloroethyl) aminophenyl]-2,6-di(trichloromethyl)-s-triazine, 4-[o-chloro-p-N,N-di(chloroethyl) aminophenyl]-2,6-di(trichloromethyl)-s-triazine, 4-[o-fluoro-p-N,N-di(chloroethyl) aminophenyl]-2,6-di(trichloromethyl)-s-triazine, 4-[m-bromo-p-N,N-di(chloroethyl) aminophenyl]-2,6-di(trichloromethyl)-s-triazine, 4-[m-chloro-p-N,N-di(chloroethyl) aminophenyl]-2,6-di(trichloromethyl)-s-triazine, 4-[m-fluoro-p-N,N-di(chloroethyl) aminophenyl]-2,6-di(trichloromethyl)-s-triazine, 4-(m-bromo-p-N-ethoxycarbonylmethyl aminophenyl)-2,6-di(trichloromethyl)-s-triazine, 4-(m-chloro-p-N-ethoxycarbonylmethyl aminophenyl)-2,6-di(trichloromethyl)-s-triazine, 4-(m-fluoro-p-N-ethoxycarbonylmethyl aminophenyl)-2,6-di(trichloromethyl)-s-triazine, 4-(o-bromo-p-N-ethoxycarbonylmethyl aminophenyl)-2,6-di(trichloromethyl)-s-triazine, 4-(o-chloro-p-N-ethoxycarbonylmethyl aminophenyl)-2,6-di(trichloromethyl)-s-triazine,

4-(o-fluoro-p-N-ethoxycarbonylmethyl aminophenyl)-2,6-di(trichloromethyl)-s-triazine, 4-(m-bromo-p-N-chloroethyl aminophenyl)-2,6-di(trichloromethyl)-s-triazine, 4-(m-chloro-p-N-chloroethyl aminophenyl)-2,6-di(trichloromethyl)-s-triazine, 4-(m-fluoro-p-N-chloroethyl aminophenyl)-2,6-di(trichloromethyl)-s-triazine, 4-(o-bromo-p-N-chloroethyl aminophenyl)-2,6-di(trichloromethyl)-s-triazine, 4-(o-chloro-p-N-chloroethyl aminophenyl)-2,6-di(trichloromethyl)-s-triazine, 4-(o-fluoro-p-N-chloroethyl aminophenyl)-2,6-di(trichloromethyl)-s-triazine.

In addition to these, the following compounds are desirably used as the photopolymerization initiator: TAZ series manufactured by Midori Kagaku Co., Ltd. (for example, TAZ-107, TAZ-110, TAZ-104, TAZ-109, TAZ-140, TAZ-204, TAZ-113, and TAZ-123), T series manufactured by PANCHIM Co., Ltd. (for example, T-OMS, T-BMP, T-R, and T-B), Irgacure series manufactured by Ciba-Geigy, Corp. (for example, Irgacure 651, Irgacure 184, Irgacure 500, Irgacure 1000, Irgacure 149, Irgacure 819, and Irgacure 261), Darocur series (for example, Darocur 1173), 4,4′-bis(diethylamino)-benzophenone, 2-(O-benzoyloxime)-1-[4-(phenylthio) phenyl]-1,2-octane dion, 2-benzyl-2-dimethylamino-4-morpholinobutyrophenone, 2,2-dimethoxy-2-phenyl acetophenone, 2-(o-chlorophenyl)-4,5-diphenylimidazolyl dimer, 2-(o-fluorophenyl)-4,5-diphenylimidazolyl dimer, 2-(o-methoxyphenyl)-4,5-diphenylimidazolyl dimer, 2-(p-methoxyphenyl)-4,5-diphenylimidazolyl dimer, 2-(p-dimethoxyphenyl)-4,5-diphenylimidazolyl dimer, 2-(2,4-dimethoxyphenyl)-4,5-diphenylimidazolyl dimer, 2-(p-methylmercaptophenyl)-4,5-diphenylimidazolyl dimer and benzoin isopropyl ether.

These photo-polymerization initiator may be used in combination with a sensitizer and a photo-stabilizer. Specific examples of these include benzoin, benzoin methyl ether, 9-fluorenone, 2-chloro-9-fluorenone, 2-methyl-9-fluorenone, 9-anthrone, 2-bromo-9-anthrone, 2-ethyl-9-anthrone, 9, 10-anthraquinone, 2-ethyl-9,10-anthraquinone, 2-t-butyl-9, 10-anthraquinone, 2,6-dichloro-9, 10-anthraquinone, xanthone, 2-methylxanthone, 2-methoxyxanthone, 2-ethoxyxanthone, thioxanthone, 2,4-diethylthioxanthone, acridone, 10-butyl-2-chloroacridone, benzyl, dibenzyl acetone, p-(dimethylamino) phenylstyryl ketone, p-(dimethylamino) phenyl-p-methylstyryl ketone, benzophenone, p-(dimethylamino) benzophenone (or Michler's ketone), p-(diethylamino) benzophenone, benzoanthrone, benzothiazole type compounds and the like described in JP-B No. 51-48516, Tinuvin 1130 and Tinuvin 400.

In addition to the photopolymerizable initiators, other known initiators can be used in the dye-containing negative-type curable composition of the invention.

Specifically, vicinal polyketol aldonyl compounds disclosed in U.S. Pat. No. 2,367,660, α-carbonyl compounds disclosed in U.S. Pat. Nos. 2,367,661 and 2,367,670, acyloin ethers disclosed in U.S. Pat. No. 2,448,828, aromatic acyloin compounds substituted with an α-hydrocarbon disclosed in U.S. Pat. No. 2,722,512, multinuclear quinone compounds disclosed in U.S. Pat. Nos. 3,046,127 and 2,951,758, a combination of triaryl imidazole dimer/p-aminophenyl ketone disclosed in U.S. Pat. No. 3,549,367, benzothiazole compound/trihalomethyl-s-triazine compound disclosed in JP-B No. 51-48516, etc.

The total content of the photopolymerization initiator (and a known initiator) used is preferably 0.01 to 50% by mass, more preferably 1 to 30% by mass, and still more preferably 1 to 20% by mass, based on the total solids content (mass) of the photopolymerizable compound described later. When the amount of the initiator used is in the range of 0.01 to 50% by mass, the polymerization reaction easily proceeds, and can enhance the strength of a coating without reducing the molecular weight.

(D) Photopolymerizable Compound

Now, the photopolymerizable compound is described. The photopolymerizable compound includes, for example, radical polymerizable monomers. The radical polymerizable monomer is preferably a compound having at least one addition-polymerizable ethylenically double bond and a boiling point of 100° C. or more at normal pressures.

The radical polymerizable monomer includes, for example, monofunctional acrylates or methacrylates such as polyethylene glycol mono(meth)acrylate, polypropylene glycol mono(meth)acrylate and phenoxyethyl (meth)acrylate; polyethylene glycol di(meth)acrylate; trimethylol ethane tri(meth)acrylate; neopentyl glycol di(meth)acrylate; pentaerythritol tri(meth)acrylate; pentaerythritol tetra(meth)acrylate; dipentaerythritol penta(meth)acrylate; dipentaerythritol hexa(meth)acrylate; hexane diol (meth)acrylate; trimethylol propane tri(acryloyloxypropyl) ether, tri(acryloyloxyethyl) isocyanurate; (meth)acrylate obtained by adding ethylene oxide or propylene oxide to a multifunctional alcohol such as glycerin or trimethylol ethane; urethane acrylates described in JP-B Nos. 48-41708, 50-6034 and JP-A No. 51-37193, polyester acrylates described in JP-A No. 48-64183, JP-B Nos. 49-43191 and 52-30490, and multifunctional acrylates and methacrylates such as epoxy acrylates that are reaction products of epoxy resin with (meth)acrylic acid. Further, photocurable monomers and oligomers described in The Journal of Adhesion Society of Japan, Vol. 20, No. 7, pp. 300-308 can also be mentioned.

The content of the photopolymerizable compound in the dye-containing negative-type curable composition is preferably 0.1 to 90% by mass, more preferably 1.0 to 80% by mass, and still more preferably 2.0 to 70% by mass, based on the solids content (mass) of the composition. When the content is in the range of 0.1 to 90% by mass, there is no change in viscosity of the dye-containing negative-type curable composition during storage, and dense coating formation by exposure to light becomes possible.

Crosslinking Agent

In the invention, it is possible to obtain a coating that is cured to a higher degree by additionally using a crosslinking agent. The crosslinking agent will be explained in the following.

The crosslinking agent to be applied to the invention is not particularly limited as long as it carries out a coating curing process through a crosslinking reaction. Examples thereof include (a) epoxy resin, (b) a melamine compound, a guanamine compound, a glycol uryl compound or an urea compound that is substituted by at least one substituent selected from the group consisting of a methylol group, an alkoxymethyl group and an acyloxymethyl group, and (c) a phenol compound, a naphthol compound or a hydroxyl anthracene that is substituted by at least one substituent selected from the group consisting of a methylol group, an alkoxymethyl group and an acyloxymethyl group. Among these, polyfunctional epoxy resin is preferably used.

As (a) epoxy resin, any resin may be used as long as it has an epoxy group and a crosslinking property. Examples thereof include divalent glycidyl group-containing low molecular compounds, such as bisphenol A diglycidyl ether, ethylene glycol diglycidyl ether, butane diol diglycidyl ether, hexane diol diglycidyl ether, dihydroxy biphenyl diglycidyl ether, phthalic acid diglycidyl ether and N,N-diglycidyl aniline; also trivalent glycidyl group-containing low molecular compounds, such as trimethylol propane triglycidyl ether, trimethylol phenol triglycidyl ether, Tris P-PA triglycidyl ether, also tetravalent glycidyl group-containing low molecular compounds, such as pentaerythritol tetraglycidyl ether and tetramethylol bisphenol A tetraglycidyl ether; also polyvalent glycidyl group-containing low molecular compounds, such as dipentaerythritol pentaglycidyl ether and dipentaerythritol hexa glycidyl ether; and also glycidyl group-containing polymer compounds, such as polyglycidyl(meth)acrylate and 1,2-epoxy-4-(2-oxyranyl) cyclohexane adduct of 2,2-bis(hydroxymethyl)-1-butanol.

The number of substituting methylol group, alkoxy methyl group and acyloxy methyl group in the crosslinking agent (b) is 2 to 6 in the case of a melamine compound, and 2 to 4 in the case of a glycol uryl compound, a guanamine compound and an urea compound. More preferably, it is 5 to 6 in the case of a melamine compound, and 3 to 4 in the case of a glycol uryl compound, a guanamine compound and an urea compound.

Hereinafter, the above-mentioned (b) melamine compound, guanamine compound, glycol uryl compound and urea compound are also generally referred to as a compound related to (b) (methylol group-containing compound, alkoxy methyl group-containing compound or acyloxy methyl group-containing compound).

The abovementioned methylol group-containing compound related to (b) is obtained by heating the alkoxy methyl group-containing compound related to (b) in alcohol in the presence of an acidic catalyst such as hydrochloric acid, sulfuric acid, nitric acid and methane sulfonic acid. The above-mentioned acyloxy methyl group-containing compound related to (b) is obtained by mixing and stirring the methylol group-containing compound related to (b) with acyl chloride in the presence of a basic catalyst.

Specific examples of compounds related to (b) having the above-mentioned substituent include the following.

Examples of the melamine compound include hexamethylol melamine, hexamethoxymethyl melamine and a compound in which 1 to methylol groups of hexamethylol melamine are methoxy-methylated or mixtures thereof. Examples of the melamine compound also include hexamethoxy ethyl melamine, hexaacyloxy methyl melamine and a compound in which 1 to 5 methylol groups of hexamethylol melamine are acyloxy-methylated or mixtures thereof.

Examples of the above-mentioned guanamine compound include tetramethylol guanamine, tetramethoxy methyl guanamine and compounds in which 1 to 3 methylol groups of tetramethylol guanamine are methoxy-methylated or mixtures thereof, and tetramethoxy ethyl guanamine, tetraacyloxy methyl guanamine and compounds in which 1 to 3 methylol groups of tetramethylol guanamine are acyloxy-methylated or mixtures thereof.

Examples of the above-mentioned glycol uryl compound include tetramethylol glycol uryl, tetramethoxy methyl glycol uryl and compounds in which 1 to 3 methylol groups of tetramethylol glycol uryl are methoxy-methylated or mixtures thereof, and compounds in which 1 to 3 methylol groups of tetramethylol glycol uryl are acyloxy-methylated or mixtures thereof.

Examples of the above-mentioned urea compound include tetramethylol urea, tetramethoxy methyl urea and compounds in which 1 to 3 methylol groups of tetramethylol urea are methoxy-methylated or mixtures thereof, and tetramethoxy ethyl urea.

These compounds related to (b) may be used alone, or may be used in combination.

The above-mentioned crosslinking agent (c), that is, a phenol compound, a naphthol compound or a hydroxy anthracene compound which is substituted by at least one group selected from the group consisting of a methylol group, an alkoxy methyl group and an acyloxy methyl group, makes it possible to prevent inter-mixing with the uppercoat photoresist through thermal crosslinking, and also to further improve the coating strength in the same manner as the above-mentioned crosslinking agent (b). Hereinafter, these compounds may be generally referred to as compounds related to (c) (methylol group-containing compound, alkoxy methyl group-containing compound or acyloxy methyl group-containing compound).

With respect to a number of the at least one group selected from a methylol group, an acyloxy methyl group, and an alkoxy methyl group contained in the above-mentioned crosslinking agent (c), two groups are required per molecule at a minimum. From the viewpoint of thermal crosslinking property and storage stability, it is preferable to use a compound in which all the second and fourth positions of the phenol skeleton are substituted. Moreover, in naphthol skeleton and hydroxy anthracene skeleton, it is preferable that all the ortho position and para position of the OH group are substituted. The third position and the fifth position of the phenol compound may be substituted or unsubstitued.

Regarding the above-mentioned naphthol compound, positions other than the ortho position of the OH group may be substituted or unsubstitued.

The methylol group-containing compound related to (c) is obtained from the reaction between a compound, in which second position or fourth position of a phenolic OH group is a hydrogen atom, as a raw material and formalin in the presence of a basic catalyst, such as sodium hydroxide, potassium hydroxide, ammonia and tetraalkyl ammonium hydroxide.

The alkoxy methyl group-containing compound related to (c) is obtained by heating a methylol group-containing compound related to (c) in alcohol in the presence of an acidic catalyst such as hydrochloric acid, sulfuric acid, nitric acid, and methane sulfonic acid.

The acyloxy methyl group-containing compound related to (c) is obtained from the reaction of a methylol group-containing compound related to (c) with acyl chloride in the presence of a basic catalyst.

Examples of the skeleton compound in the crosslinking agent (c) include a phenol compound, naphthol and a hydroxy anthracene compound in which the ortho position or para position of the phenolic OH group is unsubstituted. Specific examples thereof include phenol, the isomers of cresol, 2,3-xylenol, 2,5-xylenol, 3,4-xylenol, 3,5-xylenol, bisphenols such as bisphenol A, 4,4′-bishydroxy biphenyl, Tris P-PA (manufactured by Honshu Chemical Industry Co., Ltd.), naphthol, dihydroxy naphthalene and 2,7-dihydroxy anthracene.

Examples of the crosslinking agent (c) include trimethylol phenol, tri(methoxymethyl)phenol and compounds in which 1 to 2 methylol groups of trimethylol phenol are methoxy-methylated, trimethylol-3-cresol, tri(methoxymethyl)-3-cresol, compounds in which 1 to 2 methylol groups of trimethylol-3-cresol are methoxy-methylated, dimethylol cresol such as 2,6-dimethylol-4-cresol, tetramethylol bisphenol A, tetramethoxy methyl bisphenol A, compounds in which 1 to 3 methylol groups of tetramethylol bisphenol A are methoxy-methylated, tetramethylol-4,4′-bishydroxy biphenyl, tetramethoxymethyl-4,4′-bishydroxy biphenyl, hexamethylol form of Tris P-PA, hexamethoxymethyl form of Tris P-PA, compounds in which 1 to 5 methylol groups of hexamethylol form of Tris P-PA are methoxy-methylated and bishydroxy methyl naphthalene diol.

Moreover, examples of the hydroxy anthracene compound include 1,6-dihydroxymethyl-2,7-dihydroxy anthracene, etc.

Furthermore, examples of the acyloxymethyl group-containing compound include compounds in which a part or all of the methylol groups of the methylol group-containing compound are acyloxy-methylated.

Among these compounds, preferable compounds are trimethylol phenol, bishydroxymethyl-p-cresol, tetramethylol bisphenol A, a hexamethylol form of Tris P-PA (manufactured by Honshu Chemical Industry Co., Ltd.) and phenol compounds in which methylol groups of these compounds are substituted by alkoxymethyl groups or methylol and alkoxymethyl groups.

These compounds related to (c) may be used alone or in combination.

The total content of the crosslinking agents in the dye-containing negative-type curable composition is varied depending on the kind of material, but is preferably 1 to 70% by mass, more preferably 5 to 50% by mass, and still more preferably 7 to 30% by mass, based on the solids content (mass) of the curable composition.

Thermal-Polymerization Inhibitor

In addition to the compounds described above, a thermal-polymerization inhibitor is preferably added to the dye-containing negative-type curable composition of the invention. Thermal-polymerization inhibitors such as hydroquinone, p-methoxy phenol, di-t-butyl-p-cresol, pyrogallol, t-butyl catechol, benzoquinone, 4,4′-thiobis(3-methyl-6-t-butylphenol), 2,2′-methylenebis(4-methyl-6-t-butylphenol) and 2-mercaptobenzimidazole are useful.

(E) Organic Solvent

Hereinafter, the organic solvent contained in the first dye-containing negative-type curable composition of the invention and the organic solvent contained in the second dye-containing negative-type curable composition of the invention will be described respectively.

First Dye-Containing Negative-Type Curable Composition

The first dye-containing negative-type curable composition of the invention comprises two or more kinds of organic solvents. Two or more kinds of organic solvents used in preparation of the first dye-containing negative-type curable composition of the invention are basically not particularly limited insofar as they satisfy the solubility of each component and the coating properties of the dye-containing negative-type curable composition, but preferably the organic solvents are selected particularly in consideration of the solubility of the dye and binder, coating properties, and safety. The combination of two or more kinds of organic solvents is preferably at least one combination selected from a combination of solvents different in chemical structure, a combination of an organic solvent having a specific substituent and an organic solvent not having the specific substituent, a combination of organic solvents different in boiling point, a combination of organic solvents different in molecular weight, and a combination of organic solvents different in viscosity.

The first dye-containing negative-type curable composition of the invention comprises at least two kinds of preferable organic solvents selected from these organic solvents thereby achieving more useful effects than those of the composition comprising only one organic solvent. The organic solvent in the first dye-containing negative-type curable composition of the invention preferably comprises a hydroxyl-containing organic solvent and a hydroxyl-free organic solvent, and is more preferably a mixture containing a hydroxyl-containing organic solvent and a hydroxyl-free organic solvent, and particularly preferably comprises a hydroxyl-containing organic solvent and a hydroxyl-free, ketone group-containing organic solvent.

Preferable examples of the organic solvent include esters such as ethyl acetate, n-butyl acetate, isobutyl acetate, amyl formate, isoamyl acetate, isobutyl acetate, butyl propionate, isopropyl butyrate, ethyl butyrate, butyl butyrate, alkyl esters, methyl lactate, ethyl lactate, methyl oxyacetate, ethyl oxyacetate, butyl oxyacetate, methyl methoxyacetate, ethyl methoxyacetate, butyl methoxyacetate, methyl ethoxyacetate, ethyl ethoxyacetate, etc.;
alkyl 3-oxypropionate such as methyl 3-oxypropionate and ethyl 3-oxypropionate (for example, methyl 3-methoxypropionate, ethyl 3-methoxypropionate, methyl 3-ethoxypropionate, ethyl 3-ethoxypropionate, etc.); alkyl 2-oxypropionate such as methyl 2-oxypropionate, ethyl 2-oxypropionate and propyl 2-oxypropionate (for example, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, ethyl 2-ethoxy-2-methylpropionate, etc.); methylpyruvate, ethyl pyruvate, propyl pyruvate, methyl acetoacetate, ethyl acetoacetate, methyl 2-oxybutanoate, ethyl 2-oxobutanoate, etc.;
ethers (for example, diethylene glycol dimethyl ether, tetrahydrofuran, ethylene glycol monomethyl ether, ethylene glycol monoethyl ether, methyl Cellosolve acetate, ethyl Cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, propylene glycol monopropyl ether acetate, etc.); ketones (for example, methyl ethyl ketone, cyclohexanone, 2-heptanone, 3-heptanone, etc.); and aromatic hydrocarbons (for example, toluene, xylene, etc.).

In the first dye-containing negative-type curable composition of the invention, two or more kinds of organic solvents among these organic solvents can be arbitrarily mixed, but preferably the hydroxyl-containing organic solvent (for example, methyl lactate, ethyl lactate, propylene glycol monomethyl ether, propylene glycol monoethyl ether etc.) is mixed with the hydroxyl-free organic solvent, as described above. The hydroxyl-free organic solvent is preferably a ketone group-containing organic solvent, and from the viewpoint of increasing the degree of remaining color on a light-exposed region, a cyclic ketone group-containing organic solvent is more preferable. For example, the hydroxyl-free organic solvent is preferably methyl ethyl ketone, cyclohexanone, 2-heptanone, propylene glycol monomethyl ether acetate or the like, more preferably methyl ethyl ketone, cyclohexanone or 2-heptanone, still more preferably cyclohexanone.

When a combination of two or more kinds of organic solvents is used, the amount of each organic solvent can be suitably determined in such a range that the effect of the invention is not deteriorated. For example, when the hydroxyl-containing organic solvent and the hydroxyl-free organic solvent are simultaneously used, the ratio thereof (molar ratio of the hydroxyl-containing organic solvent/the hydroxyl-free organic solvent) is preferably 5/95 to 95/5, more preferably 10/90 to 90/10. When the content is in the range of 5/95 to 95/5, the composition is excellent from the viewpoint of solubility and coating properties, and can form an excellent coating film.

Second Dye-Containing Negative-Type Curable Composition

The second dye-containing negative-type curable composition of the invention is prepared by using an organic solvent. The organic solvent in the second dye-containing negative-type curable composition is basically not particularly limited insofar as the organic solvent contains the high-boiling solvent of the invention, and satisfies the solubility of each component and the coating properties of the dye-containing negative-type curable composition, and the organic solvent is selected particularly preferably in consideration of the solubility of the dye and binder, coating properties, and safety.

The organic solvent used in the second dye-containing negative-type curable composition of the invention contains at least a high-boiling solvent having a boiling point of 160° C. or more. The high-boiling solvent of the invention is selected particularly preferably in consideration of the solubility of the dye and binder, coating properties, and safety.

When the boiling point of the high-boiling solvent of the invention is lower than 160° C., coating properties are deteriorated to make uniform coating impossible.

It is necessary that the high-boiling solvent of the invention can be evaporated in a drying step after application to form a coating, and thus the upper limit of the boiling point is lower than the temperature at which the solvent can be evaporated in the drying step. Specifically, the boiling point of the high-boiling solvent of the invention is preferably 160 to 270° C., more preferably 180 to 250° C. When the boiling point of the high-boiling solvent of the invention is 160 to 270° C., coating uniformity can be improved.

The boiling point of the high-boiling solvent refers to a boiling point at 1 atom (0.101×10⁶ Pa).

The organic solvent in the second dye-containing negative-type curable composition of the invention preferably contains a low-boiling solvent together with the high-boiling solvent of the invention. In other words, the organic solvent in the second dye-containing negative-type curable composition is preferably the one simultaneously using the high-boiling solvent of the invention and a low-boiling solvent. That is, the organic solvent in the second dye-containing negative-type curable composition of the invention preferably contains the high-boiling solvent of the invention and a low-boiling solvent. In the invention, the low-boiling solvent refers to a solvent having a boiling point of lower than 160° C. The boiling point of the low-boiling solvent is preferably 155° C. or less from the viewpoint of coating properties, working efficiency etc., and specifically the boiling point is preferably 120 to 155° C., more preferably 140 to 155° C.

When the high- and low-boiling solvents of the invention are simultaneously used, the difference in boiling point between the two solvents is preferably 5 to 150° C., more preferably 10 to 100° C. When the difference in boiling point between the high- and low-boiling solvents is 5 to 100° C., coating properties are significantly improved. Specifically, a combination of a high-boiling solvent having a boiling point of 160 to 270° C. and a low-boiling solvent having a boiling point of 120 to 155° C. is preferable, and a combination of a high-boiling solvent having a boiling point of 160 to 250° C. and a low-boiling solvent having a boiling point of 140 to 155° C. is further preferable.

The high-boiling solvent includes cyclic carbonates such as ethylene carbonate (boiling point 243° C.) and propylene carbonate (boiling point 240° C.); alkylene glycol diacetates such as propylene glycol diacetate (boiling point 191° C.); and propylene glycol butyl ether (boiling point 165 to 170° C.). However, the high-boiling solvent of the invention is not limited to such structures, and may be a solvent having a boiling point of 160° C. or more.

Among those enumerated above, the high-boiling solvent of the invention is more preferably ethylene carbonate, propylene carbonate, propylene glycol diacetate, propylene glycol butyl ether or the like.

The low-boiling solvent includes esters (for example, ethyl acetate, n-butyl acetate, isobutyl acetate, amyl formate, isoamyl acetate, isobutyl acetate, butyl propionate, isopropyl butyrate, ethyl butyrate, butyl butyrate, alkyl esters, methyl lactate, ethyl lactate, methyl oxyacetate, ethyl oxyacetate, butyl oxyacetate, methyl methoxyacetate, ethyl methoxyacetate, butyl methoxyacetate, methyl ethoxyacetate, ethyl ethoxyacetate, etc.);
alkyl 3-oxypropionate such as methyl 3-oxypropionate and ethyl 3-oxypropionate (for example, methyl 3-methoxypropionate, ethyl 3-methoxypropionate, methyl 3-ethoxypropionate, ethyl 3-ethoxypropionate, etc.); alkyl 2-oxypropionate such as methyl 2-oxypropionate, ethyl 2-oxypropionate and propyl 2-oxypropionate (for example, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, ethyl 2-ethoxy-2-methylpropionate, etc.); methylpyruvate, ethyl pyruvate, propyl pyruvate, methyl acetoacetate, ethyl acetoacetate, methyl 2-oxybutanoate, ethyl 2-oxobutanoate, etc.;
ethers (for example, diethylene glycol dimethyl ether, tetrahydrofuran, ethylene glycol monomethyl ether, ethylene glycol monoethyl ether, methyl Cellosolve acetate, ethyl Cellosolve acetate, diethylene glycol monomethyl ether, diethylene glycol monoethyl ether, diethylene glycol monobutyl ether, propylene glycol monomethyl ether, propylene glycol methyl ether acetate, propylene glycol ethyl ether acetate, propylene glycol propyl ether acetate, etc.);
ketones (for example, methyl ethyl ketone, cyclohexanone, 2-heptanone, 3-heptanone, etc.); and aromatic hydrocarbons (for example, toluene, xylene, etc.).

Preferably used among the low-boiling solvents described above are methyl 3-ethoxypropionate, ethyl 3-ethoxypropionate, ethyl Cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether, propylene glycol methyl ether acetate etc.

Specifically, the organic solvent in the second dye-containing negative-type curable composition of the invention is preferably a combination of ethyl lactate (boiling point 154° C.) and at least one member selected from propylene carbonate (boiling point 240° C.), ethylene carbonate (boiling point 243° C.), propylene glycol diacetate (boiling point 191° C.) and propylene glycol butyl ether acetate (boiling point 165 to 170° C.).

The content of the high-boiling solvent in the organic solvent used in the second dye-containing negative-type curable composition of the invention is preferably 0.5 to 20.0 parts by mass, more preferably 0.5 to 10.0 parts by mass, based on 100 parts by mass of the organic solvent (the total amount of the solvents constituting the organic solvent: for example, the total amount of the low-boiling solvent and the high-boiling solvent). When the content of the high-boiling solvent in the organic solvent is in the range of 0.5 to 20.0 parts by mass, it possible to improve not only the uniformity of a coating but also the productivity of the coating.

In one embodiment of the second dye-containing negative-type curable composition of the invention, the organic solvent of the invention contains the high- and low-boiling solvents of the invention. Accordingly, the content of the low-boiling solvent is preferably 80 to 99.5 parts by mass (more preferably 90 to 99.5 parts by mass), and the content of the high-boiling solvent is preferably 0.5 to 20.0 parts by mass (more preferably 0.5 to 10 parts by mass), based on 100 parts by mass of the organic solvent.

Various Additives

The dye-containing negative-type curable composition of the invention can contain if necessary various additives such as fillers, polymer compounds other than those described above, a surfactant, an adhesion promoter, an antioxidant, a UV absorber, an aggregation inhibitor etc.

Examples of the various additives include fillers such as glass and alumina; polymer compounds such as polyvinyl alcohol, polyacrylic acid, polyethylene glycol monoalkyl ether and polyfluoroalkyl acrylate other than binder resin; surfactants such as nonionic, cationic or anionic surfactants; adhesion promoters such as vinyl trimethoxy silane, vinyl triethoxy silane, vinyl tris(2-methoxyethoxy) silane, N-(2-aminoethyl)-3-aminopropylmethyl dimethoxy silane, N-(2-aminoethyl)-3-aminopropyl trimethoxy silane, 3-aminopropyl triethoxy silane, 3-glycidoxypropyl trimethoxy silane, 3-glycidoxy propylmethyl dimethoxy silane, 2-(3,4-epoxycyclohexyl)ethyl trimethoxy silane, 3-chloropropylmethyl dimethoxy silane, 3-chloropropyl trimethoxy silane, 3-methacryloxy propyltrimethoxy silane and 3-mercaptopropyl trimethoxy silane; antioxidants such as 2,2-thiobis(4-methyl-6-t-butylphenol) and 2,6-di-t-butyl phenol; UV absorbers such as 2-(3-t-butyl-5-methyl-2-hydroxyphenyl)-5-chlorobenzotriazole and alkoxy benzophenone; and aggregation inhibitors such as polysodium acrylate.

For improving the alkali solubility of a non-image region and further improving the developability of the dye-containing negative-type curable composition of the invention, an organic carboxylic acid, preferably a low-molecular organic carboxylic acid having a molecular weight of 1000 or less, can be added to the composition.

Examples of the organic carboxylic acid include aliphatic monocarboxylic acids such as formic acid, acetic acid, propionic acid, butyric acid, valeric acid, pivalic acid, caproic acid, diethylacetic acid, enanthic acid and caprylic acid; aliphatic dicarboxylic acids such as oxalic acid, malonic acid, succinic acid, glutaric acid, adipic acid, pimelic acid, suberic acid, azelaic acid, sebacic acid, brassylic acid, methylmalonic acid, ethylmalonic acid, dimethylmalonic acid, methylsuccinic acid, tetramethylsuccinic acid and citraconic acid; aliphatic tricarboxylic acids such as tricarballylic acid, aconitic acid and camphoronic acid; aromatic monocarboxylic acids such as benzoic acid, toluic acid, cuminic acid, hemellitic acid and mesitylenic acid; aromatic polycarboxylic acids such as phthalic acid, isophthalic acid, terephthalic acid, trimellitic acid, trimesic acid, mellophanic acid and pyromellitic acid; and other carboxylic acids such as phenylacetic acid, hydratropic acid, hydrocinnamic acid, mandelic acid, phenylsuccinic acid, atropic acid, cinnamic acid, methyl cinnamate, benzyl cinnamate, cinnamylideneacetic acid, coumaric acid and umbellic acid.

Color Filter and the Method of Producing the Same

Hereinafter, the color filter of the invention is described in more detail by reference to the method of producing the same.

In the method of producing the color filter of the invention, the first or second dye-containing negative-type curable composition of the invention described above is used.

The method of producing the color filter according to the invention comprises applying the dye-containing negative-type curable composition of the invention onto a support by a coating method such as rotation coating, cast coating or roll coating to form a radiosensitive composition layer, exposing the layer to light through a predetermined mask pattern, and developing it with a developing solution to form a negative-type color pattern (image-forming step). If necessary, the method may contain a step of curing the formed colored pattern by heating and/or light exposure.

In production of the color filter of the invention, the image forming step (and if necessary the curing step) is repeated by the number of desired hues, whereby the color filter comprising the desired hues can be produced. The light or radiations used in this step is particularly preferably ultraviolet rays such as g ray, h ray and i ray.

Examples of the support include soda glass used in liquid crystal display devices etc., Pyrex (R) glass and quartz glass onto which a transparent electroconductive coating may be struck, as well as photoelectron conversion element substrates used in pickup devices, for example a silicon substrate and a complementary metal oxide semiconductor (CMOS). These supports may be provided with black stripes for dividing each pixel.

The support may be provided if necessary with an undercoat layer for improving adhesion thereof to the upper layer or preventing the diffusion of materials, or flattening the surface of the substrate.

Any developing solutions can be used insofar as they are composed of a composition in which an uncured region of the dye-containing negative-type curable composition of the invention is dissolved, whereas an irradiated region is not dissolved. Specifically, a combination of various organic solvents or an aqueous alkaline solution can be used as the developing solution. The organic solvents include the above-mentioned organic solvents used in preparing the dye-containing negative-type curable composition of the invention.

The aqueous alkaline solution is preferably an aqueous alkaline solution prepared by dissolving an alkaline compound such as sodium hydroxide, potassium hydroxide, sodium carbonate, sodium silicate, sodium metasilicate, ammonia water, ethylamine, diethylamine, dimethyl ethanolamine, tetramethyl ammonium hydroxide, tetraethyl ammonium hydroxide, choline, pyrrole, piperidine or 1,8-diazobicyclo-[5.4.0]-7-undecene at a concentration of 0.001 to 10% by mass, preferably 0.01 to 1% by mass. When a developing solution consisting of the aqueous alkaline solution is used, the support is washed generally with water after development.

The color filter of the invention can be used in solid-state image pickup devices such as liquid crystal display devices and CCD, and is particularly suitable for CCD devices, CMOS and the like of high resolution of one million or more pixels. The color filter of the invention can be used as a color filter to be installed between a light-receiving part of each pixel constituting CCD and a micro-lens for condensing light.

### EXAMPLES

Hereinafter, the present invention is described in more detail by reference to the Examples. However, the invention is not limited within the gist of the invention to the Examples below. The term “parts” refers to parts by mass unless otherwise specified.

First Dye-Containing Negative-Type Curable Composition

### Example 1

1) Preparation of the dye-Containing Negative-Type Curable Composition

The respective compounds in the following composition were mixed and dissolved to prepare the first dye-containing negative-type curable composition of the invention.

Composition

| | | |
|---|---|---|
| Propylene glycol monomethyl ether | 21.7 | parts |
| (PGME: organic solvent) | | |
| Ethyl lactate (organic solvent) | 21.7 | parts |
| Allyl methacrylate/methacrylic acid copolymer (80/20 | 40.5 | parts |
| [molar ratio]) (alkali-soluble binder) | | |
| Dipentaerythriol hexaacrylate (photopolymerizable | 6.1 | parts |
| compound) | | |
| p-Methoxyphenol (polymerization inhibitor) | 0.0061 | part |
| Photopolymerization initiator | 0.586 | part |
| (trade name: TAZ-107, manufactured by Midori Kagaku | | |
| Co., Ltd.) | | |
| Organic solvent-soluble dye (Valifast yellow 1101) | 9.0 | parts |

2) Production of a Glass Substrate Provided with an Undercoat Layer

A glass substrate (trade name: Corning 1737) was washed by sonication in 1% aqueous NaOH, then washed with water and subjected to dehydration baking (200° C./30 minutes). Then, a solution of Resist CT-2000L (manufactured by FUJIFILM Arch Co., Ltd.) was applied by a spin coater thereon to a thickness of 2 μm on the glass substrate after washing. After application, the resist was dried at 220° C. for 1 hour to form a cured coating (undercoat layer) on the glass substrate. The glass substrate provided with an undercoat layer was thus produced.

3) Light Exposure/Development (Image-Forming Step) of the Dye-Containing Negative-Type Curable Composition

The dye-containing negative-type curable composition obtained in 1) above was applied by a spin coater to a thickness of 1 μm onto the undercoat layer of the undercoat layer-stuck glass substrate obtained in 2) above, and then pre-baked at 120° C. for 120 seconds.

Then, the coating was irradiated through a 20 μm mask with 800 mJ/cm² exposure of a wavelength of 365 nm with an i-ray reduced exposure projector. After irradiation, the coating was developed at 23° C. for 60 seconds with a developing solution (trade name: CD-2000, 60% aqueous solution, manufactured by FUJIFILM Arch Co., Ltd.). Then, the coating was rinsed with running water for 20 seconds and then spray-dried to give a pattern image. Formation of the image was confirmed in a usual manner by observation under an optical microscope and with an SEM photograph.

4) Evaluation

(1) Occurrence of Missing Color in a Light-Exposed Region

The occurrence of missing color in a light-exposed region was evaluated by comparing the coating thickness and transmittance before pattern light exposure with the coating thickness and transmittance of a light-exposed region of the pattern obtained by light exposure and development.

The coating thickness was measured by a contact-needle-type coating thickness measuring instrument (trade name: DekTak, manufactured by Veeco). As the transmittance, transmittance at 420 nm was measured by a spectrometer (trade name: MCPD-1000, manufactured by Otsuka Electronics Co., Ltd.). The difference A before and after light exposure was calculated for the coating thickness and transmittance respectively. The results are shown in Table 1. A sample showing a smaller difference A is preferable.

### Example 2

A pattern image was formed in the same manner as in Example 1 except that the composition in 1) Preparation of the dye-containing negative-type curable composition was changed into the following composition to prepare the first dye-containing negative-type curable composition of the invention, and the image was evaluated in an analogous manner.

Composition

| | | |
|---|---|---|
| Propylene glycol monomethyl ether acetate | 21.7 | parts |
| (organic solvent: PGMEA) | | |
| Propylene glycol monomethyl ether | 21.7 | parts |
| (PGME: organic solvent) | | |
| Allyl methacrylate/methacrylic acid copolymer (80/20 | 40.5 | parts |
| [molar ratio]) (alkali-soluble binder) | | |
| Dipentaerythriol hexaacrylate (photopolymerizable | 6.1 | parts |
| compound) | | |
| p-Methoxyphenol (polymerization inhibitor) | 0.0061 | part |
| Photopolymerization initiator | 0.586 | part |
| (trade name: TAZ-107, manufactured by Midori Kagaku | | |
| Co., Ltd.) | | |
| Organic solvent-soluble dye (Valifast yellow 1101) | 9.0 | parts |

### Example 3

A pattern image was formed in the same manner as in Example 1 except that the composition in 1) Preparation of the dye-containing negative-type curable composition was changed into the following composition to prepare the first dye-containing negative-type curable composition of the invention, and the image was evaluated in an analogous manner.

Composition

| | | |
|---|---|---|
| Ethyl lactate (organic solvent) | 34.8 | parts |
| Cyclohexanone (organic solvent) | 8.7 | parts |
| Allyl methacrylate/methacrylic acid copolymer (80/20 | 40.5 | parts |
| [molar ratio]) (alkali-soluble binder) | | |
| Dipentaerythriol hexaacrylate (photopolymerizable | 6.1 | parts |
| compound) | | |
| p-Methoxyphenol (polymerization inhibitor) | 0.0061 | part |
| Photopolymerization initiator | 0.586 | part |
| (trade name: TAZ-107, manufactured by Midori Kagaku | | |
| Co., Ltd.) | | |
| Organic solvent-soluble dye (Valifast yellow 1101) | 9.0 | parts |

### Example 4

A pattern image was formed in the same manner as in Example 1 except that the composition in 1) Preparation of the dye-containing negative-type curable composition was changed into the following composition to prepare the first dye-containing negative-type curable composition of the invention, and the image was evaluated in an analogous manner.

Composition

| | | |
|---|---|---|
| Ethyl lactate (organic solvent) | 34.8 | parts |
| Cyclohexanone (organic solvent) | 8.7 | parts |
| Benzyl methacrylate/methacrylic acid copolymer (80/20 | 40.5 | parts |
| [molar ratio]) (alkali-soluble binder) | | |
| Dipentaerythriol hexaacrylate (photopolymerizable | 6.1 | parts |
| compound) | | |
| p-Methoxyphenol (polymerization inhibitor) | 0.0061 | part |
| Photopolymerization initiator | 0.586 | part |
| (trade name: TAZ-107, manufactured by Midori Kagaku | | |
| Co., Ltd.) | | |
| Organic solvent-soluble dye (Valifast yellow 1101) | 9.0 | parts |

### Example 5

A pattern image was formed in the same manner as in Example 1 except that the composition in 1) Preparation of the dye-containing negative-type curable composition was changed into the following composition to prepare the first dye-containing negative-type curable composition of the invention, and the image was evaluated in an analogous manner.

Composition

| | | |
|---|---|---|
| Ethyl lactate (organic solvent) | 34.8 | parts |
| Cyclohexanone (organic solvent) | 8.7 | parts |
| Benzyl methacrylate/methacrylic acid copolymer (80/20 | 40.5 | parts |
| [molar ratio]) (alkali-soluble binder) | | |
| Dipentaerythriol hexaacrylate (photopolymerizable | 6.1 | parts |
| compound) | | |
| p-Methoxyphenol (polymerization inhibitor) | 0.0061 | part |
| Photopolymerization initiator | 0.586 | part |
| (trade name: TAZ-107, manufactured by Midori Kagaku | | |
| Co., Ltd.) | | |
| Organic solvent-soluble dye (C. I. acid yellow 17) | 9.0 | parts |

### Example 6

A pattern image was formed in the same manner as in Example 1 except that the composition in 1) Preparation of the dye-containing negative-type curable composition was changed into the following composition to prepare the first dye-containing negative-type curable composition of the invention, and the image was evaluated in an analogous manner.

Composition

| | | |
|---|---|---|
| Ethyl lactate (organic solvent) | 34.8 | parts |
| 2-Heptanone (organic solvent) | 8.7 | parts |
| Benzyl methacrylate/methacrylic acid copolymer (80/20 | 40.5 | parts |
| [molar ratio]) (alkali-soluble binder) | | |
| Dipentaerythriol hexaacrylate (photopolymerizable | 6.1 | parts |
| compound) | | |
| p-Methoxyphenol (polymerization inhibitor) | 0.0061 | part |
| Photopolymerization initiator | 0.586 | part |
| (trade name: TAZ-107, manufactured by Midori Kagaku | | |
| Co., Ltd.) | | |
| Organic solvent-soluble dye (C. I. acid yellow 17) | 9.0 | parts |

### Example 7

A pattern image was formed in the same manner as in Example 1 except that the composition in 1) Preparation of the dye-containing negative-type curable composition was changed into the following composition to prepare the first dye-containing negative-type curable composition of the invention, and the image was evaluated in an analogous manner.

Composition

| | | |
|---|---|---|
| Methyl ethyl ketone (organic solvent) | 21.7 | parts |
| Cyclohexanone (organic solvent) | 21.7 | parts |
| Allyl methacrylate/methacrylic acid copolymer (80/20 | 40.5 | parts |
| [molar ratio]) (alkali-soluble binder) | | |
| Dipentaerythriol hexaacrylate (photopolymerizable | 6.1 | parts |
| compound) | | |
| p-Methoxyphenol (polymerization inhibitor) | 0.0061 | part |
| Photopolymerization initiator | 0.586 | part |
| (trade name: TAZ-107, manufactured by Midori Kagaku | | |
| Co., Ltd.) | | |
| Organic solvent-soluble dye (Valifast yellow 1101) | 9.0 | parts |

### Example 8

A pattern image was formed in the same manner as in Example 1 except that the composition in 1) Preparation of the dye-containing negative-type curable composition was changed into the following composition to prepare the first dye-containing negative-type curable composition of the invention, and the image was evaluated in an analogous manner.

Composition

| | | |
|---|---|---|
| Ethyl lactate (organic solvent) | 34.8 | parts |
| Methyl ethyl ketone (organic solvent) | 8.7 | parts |
| Allyl methacrylate/methacrylic acid copolymer (80/20 | 40.5 | parts |
| [molar ratio]) (alkali-soluble binder) | | |
| Dipentaerythriol hexaacrylate (photopolymerizable | 6.1 | parts |
| compound) | | |
| p-Methoxyphenol (polymerization inhibitor) | 0.0061 | part |
| Photopolymerization initiator | 0.586 | part |
| (trade name: TAZ-107, manufactured by Midori Kagaku | | |
| Co., Ltd.) | | |
| Organic solvent-soluble dye (Valifast yellow 1101) | 9.0 | parts |

### Comparative Example 1

A pattern image was formed in the same manner as in Example 1 except that the composition in 1) Preparation of the dye-containing negative-type curable composition was changed into the following composition to prepare a comparative dye-containing negative-type curable composition, and the image was evaluated in an analogous manner.

Composition

| | | |
|---|---|---|
| Ethyl lactate (organic solvent) | 43.5 | parts |
| Benzyl methacrylate/methacrylic acid copolymer (80/20 | 40.5 | parts |
| [molar ratio]) (alkali-soluble binder) | | |
| Dipentaerythriol hexaacrylate (photopolymerizable | 6.1 | parts |
| compound) | | |
| p-Methoxyphenol (polymerization inhibitor) | 0.0061 | part |
| Photopolymerization initiator | 0.586 | part |
| (trade name: TAZ-107, manufactured by Midori Kagaku | | |
| Co., Ltd.) | | |
| Organic solvent-soluble dye (C. I. acid yellow 17) | 9.0 | parts |

### Comparative Example 2

A pattern image was formed in the same manner as in Example 1 except that the composition in 1) Preparation of the dye-containing negative-type curable composition was changed into the following composition to prepare a comparative dye-containing negative-type curable composition, and the image was evaluated in an analogous manner.

Composition

| | | |
|---|---|---|
| Propylene glycol monomethyl ether acetate | 43.5 | parts |
| (organic solvent: PGMEA) | | |
| Allyl methacrylate/methacrylic acid copolymer (80/20 | 40.5 | parts |
| [molar ratio]) (alkali-soluble binder) | | |
| Dipentaerythriol hexaacrylate (photopolymerizable | 6.1 | parts |
| compound) | | |
| p-Methoxyphenol (polymerization inhibitor) | 0.0061 | part |
| Photopolymerization initiator | 0.586 | part |
| (trade name: TAZ-107, manufactured by Midori Kagaku | | |
| Co., Ltd.) | | |
| Organic solvent-soluble dye (Valifast yellow 1101) | 9.0 | parts |

TABLE 1

| | | | Difference Δ | Difference |
|---|---|---|---|---|
| | | | in coating | Δ in |
| | | | thickness | transmittance |
| | Organic solvent | | (μm) | (%) |
| Example 1 | PGME | Ethyl lactate | 0.05 | 1.2 |
| Example 2 | PGMEA | PGME | 0.03 | 0.8 |
| Example 3 | Ethyl lactate | Cyclohexanone | 0.01 | 0.1 |
| Example 4 | Ethyl lactate | Cyclohexanone | 0.01 | 0.1 |
| Example 5 | Ethyl lactate | Cyclohexanone | 0.01 | 0.1 |
| Example 6 | Ethyl lactate | 2-heptanone | 0.03 | 1.0 |
| Example 7 | Methyl ethyl | Cyclohexanone | 0.05 | 1.1 |
| | ketone | | | |
| Example 8 | Ethyl lactate | Methyl ethyl | 0.04 | 1.0 |
| | | ketone | | |

| | | | |
|---|---|---|---|
| Comparative | Ethyl lactate | 0.10 | 5.8 |
| Example 1 | | | |
| Comparative | PGMEA | 0.11 | 7.2 |
| Example 2 | | | |

As shown in Table 1 it was found that in the Examples where two organic solvents were mixed, the occurrence of missing color is effectively suppressed with less change in coating thickness and transmittance before and after irradiation. As shown in Examples 3 to 6, it is evident that the system using a mixture of a hydroxyl-containing organic solvent and a hydroxyl-free organic solvent is particularly excellent, and the system using a mixture of a hydroxyl-containing organic solvent and a ketone group-containing organic solvent is further more excellent.

In the Comparative Examples where only one organic solvent was used, on the other hand, the occurrence of significant missing color was recognized with significant change in coating thickness and transmittance.

Second Dye-Containing Negative-Type Curable Composition

### Example 9

1) Preparation of the Dye-Containing Negative-Type Curable Composition

The respective compounds in the following composition were mixed and dissolved to prepare the second dye-containing negative-type curable composition of the invention.

Composition

| | | |
|---|---|---|
| Ethyl lactate (low-boiling solvent: boiling point 154° C.) | 41.23 | parts |
| Propylene carbonate (high-boiling solvent: boiling | 2.17 | parts |
| point 240° C.) | | |
| Allyl methacrylate/methacrylic acid copolymer (resin A) | 40.5 | parts |
| (=80/20 [molar ratio]; alkali-soluble resin) | | |
| Dipentaerythriol hexaacrylate (photopolymerizable | 6.1 | parts |
| compound) (trade name: TAZ-107, manufactured by | | |
| Midori Kagaku Co., Ltd.) | | |
| p-Methoxyphenol (polymerization inhibitor) | 0.0061 | part |
| Photopolymerization initiator | 0.586 | part |
| (trade name: TAZ-107, manufactured by Midori Kagaku | | |
| Co., Ltd.) | | |
| Organic solvent-soluble dye (Valifast yellow 1101) | 9.0 | parts |

2) Preparation of an Evaluation Sample

A glass substrate (trade name: Corning 1737) was washed by sonication in 1% aqueous NaOH. After washing, the substrate was further washed with water and then subjected to dehydration baking (200° C./30 minutes). Then, the dye-containing negative-type curable composition obtained above was applied to a thickness of 1 μm on the substrate by a spin coater, and then pre-baked at 120° C. for 120 seconds. An evaluation sample using the dye-containing negative-type curable composition of the invention was obtained by forming its coating on the glass substrate as described above.

Evaluation

(Uniformity of Coating Surface)

To evaluate the uniformity of coating surface, the thickness of the coating of the evaluation sample obtained above was measured at arbitrary 10 points. The results are shown in Table 1.

The coating thickness was measured by a contact-needle-type coating thickness measuring instrument (trade name: DekTak, manufactured by Veeco), and the difference Δ between the maximum thickness and minimum thickness was determined.

A sample of smaller Δ is preferable.

### Examples 10 to 15

An evaluation sample was prepared in the same manner as in Example 9 except that the composition in 1) Preparation of the dye-containing negative-type curable composition was changed as shown in Table 2 to prepare the second dye-containing negative-type curable composition of the invention, and the sample was evaluated in an analogous manner. The results are shown in Table 2.

### Comparative Examples 3 to 4

A comparative evaluation sample was prepared in the same manner as in Example 9 except that the composition in 1) Preparation of the dye-containing negative-working curable composition was changed as shown in Table 2 to prepare a comparative dye-containing negative-type curable composition, and the sample was evaluated in an analogous manner. The results are shown in Table 2.

TABLE 2

| | | | | | | | | Evaluation |
|---|---|---|---|---|---|---|---|---|
| | | | | | | | | Maximum |
| | | | | | | | | difference |
| | Organic solvent | | Alkali- | | | Pho- | | in coating |
| | Low-boiling | High-boiling | soluble | Photopolymerizable | Polymerization | topolymerization | Organic solvent- | thickness |
| | solvent | solvent | resin | compound | inhibitor | initiator | soluble dye | (μm) |
| Example 9 | EL | PC | Resin A | DPHA | p-methoxyphenol | TAZ-107 | Valifast yellow 1101 | 0.01 |
| | 41.23 parts | 2.17 parts | 40.5 parts | 6.1 parts | 0.0061 parts | 0.586 parts | 9.0 parts | |
| Example 10 | EL | EC | Resin A | DPHA | p-methoxyphenol | TAZ-107 | Valifast yellow 1101 | 0.01 |
| | 41.23 parts | 2.17 parts | 40.5 parts | 6.1 parts | 0.0061 parts | 0.586 parts | 9.0 parts | |
| Example 11 | EL | PGDA | Resin A | DPHA | p-methoxyphenol | TAZ-107 | Valifast yellow 1101 | 0.01 |
| | 41.23 parts | 2.17 parts | 40.5 parts | 6.1 parts | 0.0061 parts | 0.586 parts | 9.0 parts | |
| Example 12 | EL | PGBE | Resin A | DPHA | p-methoxyphenol | TAZ-107 | Valifast yellow 1101 | 0.01 |
| | 41.23 parts | 2.17 parts | 40.5 parts | 6.1 parts | 0.0061 parts | 0.586 parts | 9.0 parts | |
| Example 13 | EL | PC | Resin A | DPHA | p-methoxyphenol | TAZ-107 | Valifast yellow 1101 | 0.06 |
| | 41.23 parts | 5.21 parts | 40.5 parts | 6.1 parts | 0.0061 parts | 0.586 parts | 9.0 parts | |
| Example 14 | EL | PC | Resin A | DPHA | p-methoxyphenol | TAZ-107 | Valifast yellow 1101 | 0.11 |
| | 43.23 parts | 0.17 parts | 40.5 parts | 6.1 parts | 0.0061 parts | 0.586 parts | 9.0 parts | |
| Example 15 | EL | PC | Resin A | DPHA | p-methoxyphenol | TAZ-107 | Valifast yellow 1101 | 0.10 |
| | 32.55 parts | 10.85 parts | 40.5 parts | 6.1 parts | 0.0061 parts | 0.586 parts | 9.0 parts | |
| Comparative | EL | — | Resin A | DPHA | p-methoxyphenol | TAZ-107 | Valifast yellow 1101 | 0.17 |
| Example 3 | 43.4 parts | | 40.5 parts | 6.1 parts | 0.0061 parts | 0.586 parts | 9.0 parts | |
| Comparative | EL | PGMEA | Resin A | DPHA | p-methoxyphenol | TAZ-107 | Valifast yellow 1101 | 0.19 |
| Example 4 | 41.23 parts | 2.17 parts | 40.5 parts | 6.1 parts | 0.0061 parts | 0.586 parts | 9.0 parts | |

EL: ethyl lactate (boiling point 154° C.)
PC: propylene carbonate (boiling point 240° C.)
EC: ethylene carbonate (boiling point 243° C.)
PGDA: propylene glycol diacetate (boiling point 191° C.)
PGBE: propylene glycol butyl ether (boiling point 165 to 170° C.)
PGMEA: propylene glycol methyl ether acetate (boiling point 145° C.)
Resin A: allyl methacrylate/methacrylic acid copolymer (=80/20 [molar ratio])
DPHA: dipentaerythritol hexaacrylate
TAZ-107: a product of Midori Kagaku Co., Ltd.

As can be seen from Table 2, the dye-containing negative-type curable composition comprising a high-boiling solvent mixed therein is superior in coating uniformity to the system not using a high-boiling solvent (Comparative Example 3) or the system using a mixture of two kinds of usual solvents (Comparative Example 4).

The invention provides a dye-containing negative-type curable composition which sufficiently suppresses the occurrence of missing color in a light-exposed region. The invention also provides a dye-containing negative-type curable composition that is excellent in coating uniformity.

The invention further provides a color filter having not only high transmittance and broad development latitude, but also high resolution and excellent light fastness, by using the dye-containing negative-type curable composition of the invention in the color filter.

Moreover, the invention also provides a color filter production method that is capable of producing a color filter excellent in resolution and heat resistance with high cost performance.

1. A dye-containing negative-type curable composition comprising at least (A) an alkali-soluble binder, (B) an organic solvent-soluble dye, (C) a photopolymerization initiator, (D) a photopolymerizable compound, and (E) an organic solvent, wherein the organic solvent (E) contains two or more kinds of organic solvents.

2. A dye-containing negative-type curable composition according to claim 1, wherein the organic solvent (E) contains a hydroxyl-containing organic solvent and a hydroxyl-free organic solvent.

3. A dye-containing negative-type curable composition according to claim 2, wherein the hydroxyl-free organic solvent is a ketone group-containing organic solvent.

4. A dye-containing negative-type curable composition according to claim 3, wherein the ketone group is a cyclic ketone group.

5. A color filter comprising a dye-containing negative-type curable composition used therein, the composition comprising at least (A) an alkali-soluble binder, (B) an organic solvent-soluble dye, (C) a photopolymerization initiator, (D) a photopolymerizable compound, and (E) an organic solvent, wherein the organic solvent (E) contains two or more kinds of organic solvents.

6. A method of producing a color filter, which comprises applying a dye-containing negative-type curable composition onto a support, exposing the composition to light through a mask, and developing the composition to form a pattern,
the composition comprising at least (A) an alkali-soluble binder, (B) an organic solvent-soluble dye, (C) a photopolymerization initiator, (D) a photopolymerizable compound, and (E) an organic solvent, wherein the organic solvent (E) contains two or more kinds of organic solvents.

7. A dye-containing negative-type curable composition comprising at least (A) an alkali-soluble binder, (B) an organic solvent-soluble dye, (C) a photopolymerization initiator, (D) a photopolymerizable compound, and (E) an organic solvent, wherein the organic solvent (E) contains a high-boiling solvent having a boiling point of 160° C. or more.

8. A dye-containing negative-type curable composition according to claim 7, wherein the boiling point of the high-boiling solvent is 160 to 270° C.

9. A dye-containing negative-type curable composition according to claim 7, wherein the organic solvent (E) further contains a low-boiling solvent.

10. A dye-containing negative-type curable composition according to claim 8, wherein the organic solvent (E) further contains a low-boiling solvent.

11. A dye-containing negative-type curable composition according to claim 9, wherein the boiling point of the low-boiling solvent is 155° C. or less.

12. A dye-containing negative-type curable composition according to claim 10, wherein the boiling point of the low-boiling solvent is 155° C. or less.

13. A dye-containing negative-type curable composition according to claim 7, wherein the organic solvent (E) contains the high-boiling solvent in an amount of 0.5 to 20.0 parts by mass based on 100 parts by mass of the organic solvent (E).

14. A dye-containing negative-type curable composition according to claim 8, wherein the organic solvent (E) contains the high-boiling solvent in an amount of 0.5 to 20.0 parts by mass based on 100 parts by mass of the organic solvent (E).

15. A dye-containing negative-type curable composition according to claim 9, wherein the organic solvent (E) contains the high-boiling solvent in an amount of 0.5 to 20.0 parts by mass based on 100 parts by mass of the organic solvent (E).

16. A dye-containing negative-type curable composition according to claim 10, wherein the organic solvent (E) contains the high-boiling solvent in an amount of 0.5 to 20.0 parts by mass based on 100 parts by mass of the organic solvent (E).

17. A dye-containing negative-type curable composition according to claim 11, wherein the organic solvent (E) contains the high-boiling solvent in an amount of 0.5 to 20.0 parts by mass based on 100 parts by mass of the organic solvent (E).

18. A dye-containing negative-type curable composition according to claim 12, wherein the organic solvent (E) contains the high-boiling solvent in an amount of 0.5 to 20.0 parts by mass based on 100 parts by mass of the organic solvent (E).

19. A color filter comprising a dye-containing negative-type curable composition used therein, the composition comprising at least (A) an alkali-soluble binder, (B) an organic solvent-soluble dye, (C) a photopolymerization initiator, (D) a photopolymerizable compound, and (E) an organic solvent, wherein the organic solvent (E) contains a high-boiling solvent having a boiling point of 160° C. or more.

20. A method of producing a color filter, which comprises applying a dye-containing negative-type curable composition onto a support, exposing the composition to light through a mask, and developing the composition to form a pattern,
the composition comprising at least (A) an alkali-soluble binder, (B) an organic solvent-soluble dye, (C) a photopolymerization initiator, (D) a photopolymerizable compound, and (E) an organic solvent, wherein the organic solvent (E) contains a high-boiling solvent having a boiling point of 160° C. or more.
